(19) United States
(12) Patent Application Publication
(10) Pub. No.: US 2025/0087493 A1
(43) Pub. Date: Mar. 13, 2025

(54) PROCESSING METHOD, METHOD OF MANUFACTURING SEMICONDUCTOR DEVICE, PROCESSING APPARATUS, AND RECORDING MEDIUM

(71) Applicant: Kokusai Electric Corporation, Tokyo (JP)

(72) Inventors: Ryota UENO, Toyama-shi (JP); Kimihiko NAKATANI, Toyama-shi (JP)

(73) Assignee: Kokusai Electric Corporation, Tokyo (JP)

(21) Appl. No.: 18/882,306

(22) Filed: Sep. 11, 2024

(30) Foreign Application Priority Data
Sep. 11, 2023 (JP) 2023-146994

(51) Int. Cl. H01L 21/311; H01L 21/67

(52) U.S. Cl. CPC H01L 21/31116; H01L 21/67069

(57) ABSTRACT

Included is etching at least a part of a surface of a concave portion by performing a cycle a predetermined number of times, the cycle including: (a) exciting and supplying a modifying agent to a substrate including the concave portion, the surface of which includes a substance containing oxygen; and (b) supplying an etching agent to the substrate in which the oxygen concentration on the surface of the upper portion of the concave portion is changed.

### CROSS-REFERENCE TO RELATED APPLICATION

This application is based upon and claims the benefit of priority from Japanese Patent Application No. 2023-146994, filed on Sep. 11, 2023, the entire contents of which are incorporated herein by reference.

### FIELD

The present disclosure relates to a processing method, a method of manufacturing a semiconductor device, a processing apparatus, and a recording medium.

### DESCRIPTION OF THE RELATED ART

As one step of steps of manufacturing a semiconductor device, processing of removing an underlayer exposed to a surface of a substrate by etching is performed in some cases.

### SUMMARY

Some embodiments of the present disclosure provide a technique of conformally etching a surface of a concave portion included in a substrate.

According to one embodiment of the present disclosure, provided is a technique including etching at least a part of a surface of a concave portion by performing a cycle a predetermined number of times, the cycle including:
(a) exciting and supplying a modifying agent to a substrate including the concave portion, the surface of which includes a substance containing oxygen, to change an oxygen concentration on a surface of an upper portion of the concave portion; and
(b) supplying an etching agent to the substrate in which the oxygen concentration on the surface of the upper portion of the concave portion is changed.

### BRIEF DESCRIPTION OF THE DRAWINGS

FIG. 1 is a schematic configuration diagram of a vertical processing furnace in a processing apparatus suitably used in one embodiment of the present disclosure, illustrating a longitudinal sectional view of a processing furnace 202.

FIG. 2 is a schematic configuration diagram of the vertical processing furnace in the processing apparatus suitably used in one embodiment of the present disclosure, illustrating a cross-sectional view of the processing furnace 202 taken along line A-A of FIG. 1.

FIG. 3 is a schematic configuration diagram of a controller 121 of the processing apparatus suitably used in one embodiment of the present disclosure, illustrating a control system of a controller 121 in a block diagram.

FIG. 4A is a partially enlarged cross-sectional view illustrating a surface portion of a substrate in one embodiment of the present disclosure including a concave portion, a surface of which includes an oxygen-containing substance. FIG. 4B is a partially enlarged cross-sectional view illustrating the surface portion of the substrate in one embodiment of the present disclosure after a modifying agent is excited and supplied from a state of FIG. 4A. FIG. 4C is a partially enlarged cross-sectional view illustrating the surface portion of the substrate in one embodiment of the present disclosure after an etching agent is supplied from a state of FIG. 4B. FIG. 4D is a partially enlarged cross-sectional view illustrating the surface portion of the substrate in one embodiment of the present disclosure after the modifying agent is excited and further supplied from a state of FIG. 4C. FIG. 4E is a partially enlarged cross-sectional view illustrating the surface portion of the substrate in one embodiment of the present disclosure after the etching agent is further supplied from a state of FIG. 4D. FIG. 4F is a partially enlarged cross-sectional view illustrating the surface portion of the substrate in one embodiment of the present disclosure after the oxidizing agent is supplied from a state of FIG. 4E.

### DETAILED DESCRIPTION

### First embodiment of Present Disclosure

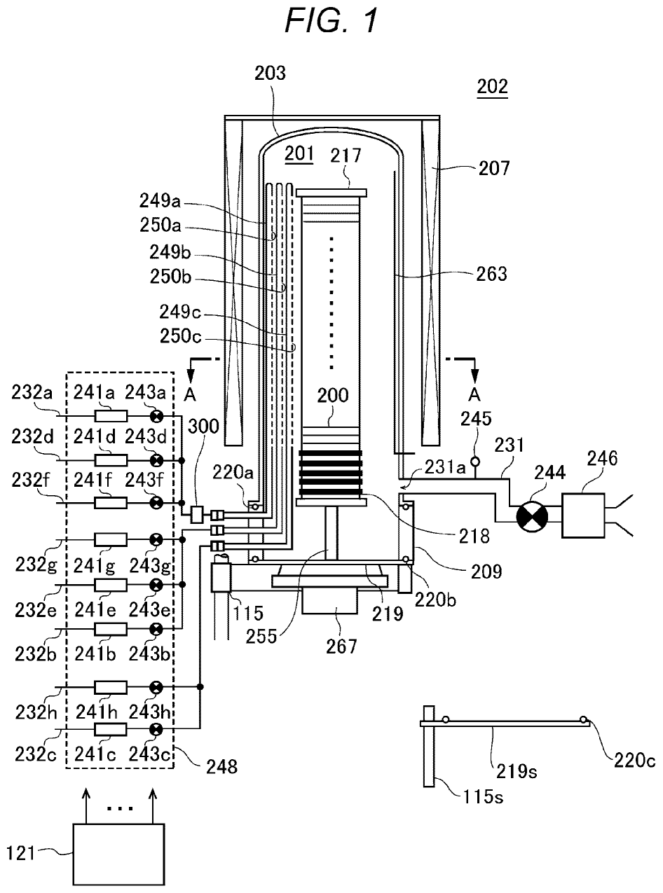

A first embodiment of the present disclosure will be hereinafter described mainly with reference to FIGS. 1 to 3 and FIGS. 4A to 4F. The drawings used in the following description are all schematic, and a dimensional relationship between respective elements, a ratio between the respective elements and the like illustrated in the drawings do not necessarily coincide with actual ones. Between a plurality of drawings, the dimensional relationship between the respective elements and the ratio between the respective elements do not necessarily coincide with each other.

### (1) Configuration of Processing Apparatus

As illustrated in FIG. 1, a processing furnace 202 of a processing apparatus includes a heater 207 as a temperature regulator (heater). The heater 207 has a cylindrical shape and is supported by a holding plate to be vertically installed. The heater 207 also functions as an activating mechanism (exciter) that thermally activates (excites) a gas.

Inside the heater 207, a reaction tube 203 is disposed concentrically with the heater 207. The reaction tube 203 is made of, for example, a heat-resistant material such as quartz (SiO₂) or silicon carbide (SiC), and is formed into a cylindrical shape with an upper end closed and a lower end opened. A manifold 209 is disposed below the reaction tube 203 concentrically with the reaction tube 203. The manifold 209 is made of a metal material such as stainless steel (SUS), for example, into a cylindrical shape with an upper end and lower end opened. The upper end of the manifold 209 engages with the lower end of the reaction tube 203 and is configured to support the reaction tube 203. An O-ring 220a as a seal member is provided between the manifold 209 and the reaction tube 203. The reaction tube 203 is vertically installed similarly to the heater 207. A processing container (reaction container) is mainly formed of the reaction tube 203 and the manifold 209. A processing chamber 201 is formed in a cylinder hollow portion of the processing container. The processing chamber 201 is configured to be able to accommodate a wafer 200 as a substrate. The wafer 200 is processed in the processing chamber 201.

In the processing chamber 201, nozzles 249a to 249c as first to third suppliers, respectively, are provided so as to penetrate a side wall of the manifold 209. The nozzles 249a to 249c are also referred to as first to third nozzles, respectively. The nozzles 249a to 249c are each made of, for example, a heat-resistant material such as quartz or SiC. Gas supply pipes 232a to 232c are connected to the nozzles 249a to 249c, respectively. The nozzles 249a to 249c are nozzles different from one another, and the nozzles 249a and 249c are provided adjacent to the nozzle 249b.

The gas supply pipes 232a to 232c are provided with mass flow controllers (MFCs) 241a to 241c as flow rate controllers (flow rate controllers), and valves 243a to 243c as opening/closing valves, respectively, in this order from an upstream side of a gas flow. Gas supply pipes 232d and 232f are connected to the gas supply pipe 232a on a downstream side of the valve 243a. Gas supply pipes 232e and 232g are connected to the gas supply pipe 232b on a downstream side of the valve 243b. A gas supply pipe 232h is connected to the gas supply pipe 232c on a downstream side of the valve 243c. The gas supply pipes 232d to 232h are provided with MFCs 241d to 241h and valves 243d to 243h, respectively, in this order from the upstream side of the gas flow. The gas supply pipes 232a to 232h are each made of, for example, a metal material such as SUS.

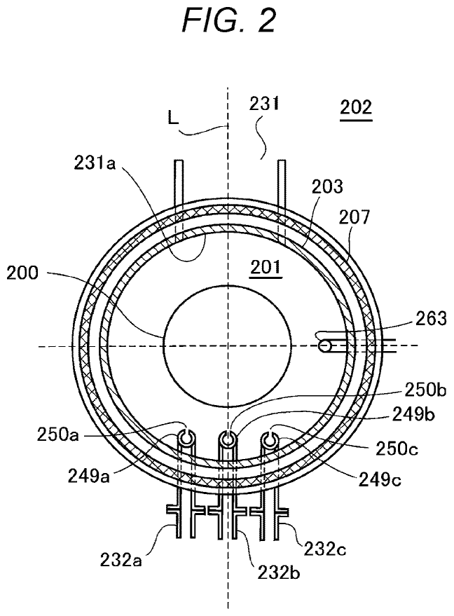

As illustrated in FIG. 2, the nozzles 249a to 249c are provided in an annular space in a plan view between an inner wall of the reaction tube 203 and the wafer 200 so as to extend upward in an arrangement direction of the wafers 200 along the inner wall of the reaction tube 203 from a lower portion to an upper portion. That is, the nozzles 249a to 249c are provided along a wafer arrangement region, in a region horizontally surrounding the wafer arrangement region, on a lateral side of the wafer arrangement region in which the wafers 200 are arranged. In a plan view, the nozzle 249b is arranged so as to be opposed to an exhaust port 231a to be described later on a straight line across the center of the wafer 200 in the processing chamber 201. The nozzles 249a and 249c are arranged so as to interpose a straight line L passing through the nozzle 249b and the center of the exhaust port 231a from both sides along the inner wall of the reaction tube 203 (outer peripheral portion of the wafer 200). The straight line L also passes through the nozzle 249b and the center of the wafer 200. That is, it can also be said that the nozzle 249c is provided on a side opposite to the nozzle 249a across the straight line L. The nozzles 249a and 249c are arranged in line symmetry with the straight line L as a symmetry axis. On side surfaces of the nozzles 249a to 249c, gas supply holes 250a to 250c through which a gas is supplied are formed, respectively. The gas supply holes 250a to 250c are each opened so as to be opposed to (face) the exhaust port 231a in a plan view, and can supply the gas toward the wafer 200. A plurality of gas supply holes 250a to 250c is formed from the lower portion to the upper portion of the reaction tube 203.

A reducing agent as a modifying agent is supplied from the gas supply pipe 232a into the processing chamber 201 via the MFC 241a, the valve 243a, and the nozzle 249a.

An etching agent is supplied from the gas supply pipe 232b into the processing chamber 201 via the MFC 241b, the valve 243b, and the nozzle 249b. The etching agent supplied from the gas supply pipe 232b is also referred to as a first substance.

An etching agent is supplied from the gas supply pipe 232c into the processing chamber 201 via the MFC 241c, the valve 243c, and the nozzle 249c. The etching agent supplied from the gas supply pipe 232c is also referred to as a second substance.

An oxidizing agent as a modifying agent is supplied from the gas supply pipe 232d into the processing chamber 201 via the MFC 241d, the valve 243d, the gas supply pipe 232a, and the nozzle 249a.

A catalyst is supplied from the gas supply pipe 232e into the processing chamber 201 via the MFC 241e, the valve 243e, the gas supply pipe 232b, and the nozzle 249b.

An inert gas is supplied from the gas supply pipes 232f to 232h into the processing chamber 201 via the MFCs 241f to 241h, the valves 243f to 243h, the gas supply pipes 232a to 232c, and the nozzles 249a to 249c, respectively. The inert gas acts as a purge gas, a carrier gas, a diluent gas and the like.

A remote plasma unit (hereinafter, RPU) 300 as a plasma exciter (plasma generator) that excites the gas into a plasma state is provided on the gas supply pipe 232a on a downstream side of a connection portion with the gas supply pipe 232f. Excitation of the gas into a plasma state is also simply referred to as plasma excitation of the gas. By applying radio-frequency (RF) power, the RPU 300 can turn the gas into a plasma state to excite inside the RPU 300, that is, excite the gas into a plasma state. As a plasma generation method, a capacitively coupled plasma (abbreviated as CCP) method or an inductively coupled plasma (abbreviated as ICP) method may be used. The RPU 300 is configured to be able to excite the modifying agent or the inert gas supplied from the gas supply pipes 232a, 232d, and 232f into a plasma state and supply the same into the processing chamber 201. The RPU 300 is also simply referred to as the exciter.

A reducing agent supply system is mainly formed of the gas supply pipe 232a, the MFC 241a, and the valve 243a. An etching agent (first substance) supply system is mainly formed of the gas supply pipe 232b, the MFC 241b, and the valve 243b. An etching agent (second substance) supply system is mainly formed of the gas supply pipe 232c, the MFC 241c, and the valve 243c. An oxidizing agent supply system is mainly formed of the gas supply pipe 232d, the MFC 241d, and the valve 243d. A catalyst supply system is mainly formed of the gas supply pipe 232e, the MFC 241e, and the valve 243e. An inert gas supply system is mainly formed of the gas supply pipes 232f to 232h, the MFCs 241f to 241h, and the valves 243f to 243h. Each of or both the reducing agent supply system and the oxidizing agent supply system is also referred to as a modifying agent supply system. The RPU 300 may be included in the modifying agent supply system.

Any one or all of the various supply systems described above may be configured as an integrated supply system 248 in which the valves 243a to 243h, the MFCs 241a to 241h and the like are integrated. The integrated supply system 248 is connected to each of the gas supply pipes 232a to 232h, and is configured such that a supplying operation of various substances (various gases) into the gas supply pipes 232a to 232h, that is, an opening/closing operation of the valves 243a to 243h, a flow rate regulating operation by the MFCs 241a to 241h and the like are controlled by a controller 121 to be described later. The integrated supply system 248 is configured as an integral or separated integrated unit, and can be attached to or detached from the gas supply pipes 232a to 232h and the like on an integrated unit basis, so that the integrated supply system 248 can be maintained, replaced, or added on an integrated unit basis.

The exhaust port 231a from which an atmosphere inside the processing chamber 201 is discharged is formed in a lower portion of a side wall of the reaction tube 203. As illustrated in FIG. 2, the exhaust port 231a is provided at a position opposed to (facing) the nozzles 249a to 249c (gas supply holes 250a to 250c) across the wafer 200 in a plan view. The exhaust port 231a may be provided along the side wall of the reaction tube 203 from the lower portion toward the upper portion, that is, along the wafer arrangement region. An exhaust pipe 231 is connected to the exhaust port 231a. A vacuum pump 246 as a vacuum-exhaust device is connected to the exhaust pipe 231 via a pressure sensor 245 as a pressure detector (pressure detector) that detects the pressure in the processing chamber 201 and an auto pressure controller (APC) valve 244 as a pressure regulator (pressure regulator). The APC valve 244 is configured to be able to vacuum-exhaust the processing chamber 201 and stop the vacuum-exhaust by opening and closing a valve thereof in a state in which the vacuum pump 246 is operating, and further regulate the pressure in the processing chamber 201 by adjusting a degree of valve opening on the basis of pressure information detected by the pressure sensor 245 in a state in which the vacuum pump 246 is operating. An exhaust system is mainly formed of the exhaust pipe 231, the APC valve 244, and the pressure sensor 245. The vacuum pump 246 may be included in the exhaust system.

Below the manifold 209, provided is a seal cap 219 as a furnace opening lid capable of hermetically closing the lower end opening of the manifold 209. The seal cap 219 is made of, for example, a metal material such as SUS into a disk shape. An O-ring 220b as a seal member that abuts the lower end of the manifold 209 is provided on an upper surface of the seal cap 219. A rotating mechanism 267 that rotates a boat 217 to be described later is disposed below the seal cap 219. A rotating shaft 255 of the rotating mechanism 267 penetrates the seal cap 219 and is connected to the boat 217. The rotating mechanism 267 is configured to rotate the boat 217, thereby rotating the wafer 200. The seal cap 219 is configured to be lifted up and down in a vertical direction by a boat elevator 115 as a lifting mechanism disposed outside the reaction tube 203. The boat elevator 115 is configured as a conveying device (conveying mechanism) that lifts the seal cap 219 up and down, thereby loading and unloading (conveying) the wafer 200 into/from the processing chamber 201.

Below the manifold 209, provided is a shutter 219s as a furnace opening lid capable of hermetically closing the lower end opening of the manifold 209 with the seal cap 219 lowered and the boat 217 unloaded from the processing chamber 201. The shutter 219s is made of, for example, a metal material such as SUS into a disk shape. An O-ring 220c as a seal member that abuts the lower end of the manifold 209 is provided on an upper surface of the shutter 219s. The opening/closing operation (lifting operation, turning operation and the like) of the shutter 219s is controlled by a shutter opening/closing mechanism 115s.

The boat 217 as a substrate supporter is configured to support a plurality of, for example, 25 to 200 wafers 200 horizontally, in multiple stages so as to be aligned in the vertical direction with the centers aligned with one another, that is, to arrange at intervals. The boat 217 is made of, for example, a heat-resistant material such as quartz and SiC. Heat insulating plates 218 made of a heat-resistant material such as quartz and SiC, for example, are supported in multiple stages in a lower portion of the boat 217.

In the reaction tube 203, provided is a temperature sensor 263 as a temperature detector. By regulating a degree of energization to the heater 207 on the basis of temperature information detected by the temperature sensor 263, a desired temperature distribution can be achieved in the processing chamber 201. The temperature sensor 263 is provided along the inner wall of the reaction tube 203.

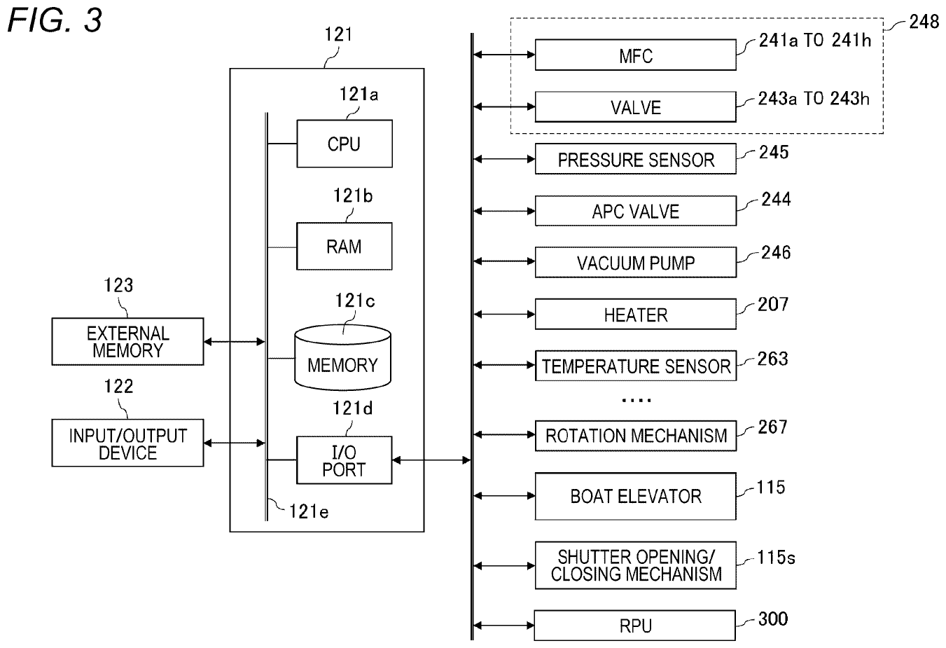

As illustrated in FIG. 3, a controller 121 as a controller (controller) is configured as a computer provided with a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An input/output device 122 configured as, for example, a touch panel and the like is connected to the controller 121. An external memory 123 can be connected to the controller 121. The processing apparatus may be provided with one controller or a plurality of controllers. That is, control for performing a processing sequence to be described later may be performed using one controller or a plurality of controllers. A plurality of controllers may be mutually connected by a wired or wireless communication network as a control system, and control for performing the processing sequence to be described later may be performed by an entire control system. In a case where the term “controller” is used in this specification, this might include a case where a plurality of controllers is included and a case where a control system formed of a plurality of controllers is included in addition to a case where one controller is included.

The memory 121c includes, for example, a flash memory, a hard disk drive (HDD), a solid state drive (SSD) and the like. In the memory 121c, a control program that controls the operation of the processing apparatus, a process recipe in which procedures, conditions and the like of substrate processing to be described later are described and the like are readably recorded and stored. The process recipe is a combination that allows the controller 121 to allow the processing apparatus to execute each procedure in the substrate processing to be described later (etching processing) to obtain a predetermined result, and serves as a program. Hereinafter, the process recipe, the control program and the like are collectively and simply referred to as a program. The process recipe is simply referred to as a recipe. In a case where the term “program” is used in this specification, this might include a case where only the recipe alone is included, a case where only the control program alone is included, or a case where both of them are included. The RAM 121b is configured as a memory area (work area) in which programs, data and the like read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotating mechanism 267, the boat elevator 115, the shutter opening/closing mechanism 115s, the RPU 300 and the like described above.

The CPU 121a is configured to be capable of reading and executing the control program from the memory 121c, and reading the recipe from the memory 121c in response to an input and the like of an operation command from the input/output device 122. The CPU 121a is configured to be capable of controlling, in accordance with a content of the read recipe, a flow rate regulating operation of various substances (various gases) by the MFCs 241a to 241h, an opening/closing operation of the valves 243a to 243h, a pressure regulating operation by the APC valve 244 on the basis of an opening/closing operation of the APC valve 244 and the pressure sensor 245, start and stop of the vacuum pump 246, a temperature regulating operation of the heater 207 on the basis of the temperature sensor 263, rotation and rotating speed adjusting operation of the boat 217 by the rotating mechanism 267, a lifting operation of the boat 217 by the boat elevator 115, an opening/closing operation of the shutter 219s by the shutter opening/closing mechanism 115s, a plasma exciting operation of a gas by the RPU 300 and the like.

The controller 121 can be formed by installing the above-described program recorded and stored in the external memory 123 into the computer. Examples of the external memory 123 include, for example, a magnetic disk such as an HDD, an optical disk such as a CD, a magneto-optical disk such as an MO, a semiconductor memory such as a USB memory, an SSD and the like. The memory 121c and the external memory 123 are configured as computer-readable recording media. Hereinafter, they are collectively and simply referred to as recording media. In a case where the term “recording medium” is used in this specification, this might include a case where only the memory 121c alone is included, a case where only the external memory 123 alone is included, or a case where both of them are included. The program may be provided to the computer by using a communication means such as the Internet and a dedicated line without using the external memory 123.

### (2) Processing Step

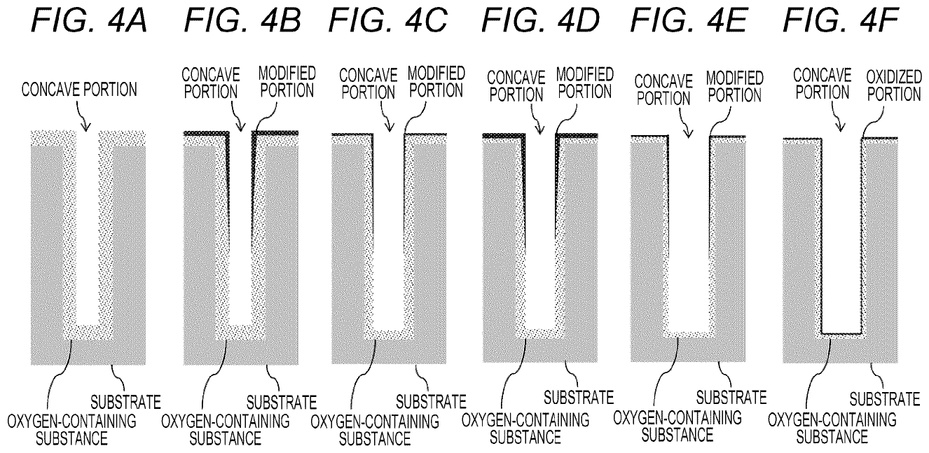

As one step of steps of a manufacturing (method of manufacturing) a semiconductor device using the processing apparatus described above, an example of a method of processing a substrate (processing method), that is, a processing sequence for etching at least a part of a surface of a concave portion of the wafer 200 as the substrate will be described mainly with reference to FIGS. 4A to 4F. In the following description, the controller 121 controls the operation of each portion forming the processing apparatus. The processing apparatus is also referred to as a substrate processing apparatus, an etching processing apparatus, or an etching apparatus. The processing method is also referred to as a substrate processing method, an etching processing method, or an etching method.

In the processing sequence in the present embodiment,
at least a part of a surface of a concave portion is etched by performing a cycle a predetermined number of times (n times: n is an integer of 1 or 2 or larger), the cycle including:
(a) step A of exciting and supplying a modifying agent to a wafer 200 including the concave portion, the surface of which includes a substance containing oxygen, to change an oxygen concentration on a surface of an upper portion of the concave portion; and
(b) step B of supplying an etching agent to the wafer 200 in which the oxygen concentration on the surface of the upper portion of the concave portion is changed. The series of processing is also referred to as etching processing.

In the following example, at step A, a case of making the oxygen concentration on the surface of the upper portion of the concave portion different from the oxygen concentration on the surface of a portion other than the upper portion of the concave portion by using the modifying agent including a reducing agent, specifically, a case of lowering the oxygen concentration on the surface of the upper portion of the concave portion than the oxygen concentration on the surface of the portion other than the upper portion of the concave portion is described. The portion other than the upper portion of the concave portion includes at least any one of a central portion, a lower portion, or a bottom portion of the concave portion. Hereinafter, the portion other than the upper portion of the concave portion is also simply referred to as a lower portion side of the concave portion.

In the following example, a case will be described in which step C of oxidizing the surface of the concave portion after the etching processing and uniformizing the oxygen concentration on the surface of the concave portion is further performed. Note that, in a case where it is not necessary to uniformize the oxygen concentration on the surface of the concave portion after the etching processing, step C can be omitted.

In this specification,, the above-described processing sequence is sometimes expressed as follows for convenience. There is a case where a similar expression is used in the following description of variations and the like.

(Modification→etching)×n→oxidation

(Modification→etching)×n

The term “wafer” used in this specification might mean the wafer itself, or a laminate of the wafer and a predetermined layer or film formed on a surface thereof. The phrase “surface of the wafer” used in this specification might mean the surface of the wafer itself or a surface of a predetermined layer and the like formed on the wafer. In this specification, the phrase “etching the surface of the wafer” might mean etching of the surface of the wafer itself, or etching of the layer or film formed on the wafer. In a case where the term “substrate” is used in this specification, this is a synonym of the term “wafer”.

The term “agent” in this specification includes at least one selected from the group of a gaseous substance and a liquid substance. The liquid substance includes a mist substance. That is, each of the modifying agent, etching agent, oxidizing agent, and catalyst may contain the gaseous substance, the liquid substance such as the mist substance, or both thereof.

### (Wafer Charge and Boat Load)

When a plurality of wafers 200 is loaded on the boat 217 (wafer charge), the shutter opening/closing mechanism 115s moves the shutter 219s, and the lower end opening of the manifold 209 is opened (shutter open). Thereafter, as illustrated in FIG. 1, the boat 217 that supports the plurality of wafers 200 is raised by the boat elevator 115 and is loaded into the processing chamber 201 (boat load). In this state, the seal cap 219 seals the lower end of the manifold 209 via the O-ring 220b. In this manner, the wafers 200 are prepared in the processing chamber 201.

As illustrated in FIG. 4A, the wafer 200 loaded on the boat 217 includes the concave portion such as a hole and a trench on the surface thereof. The surface of the concave portion includes a substance containing oxygen (oxygen-containing substance), that is, an oxide. In other words, the surface of the concave portion is made of a substance containing oxygen (oxygen-containing substance), that is, an oxide. The surface of the concave portion can include a substance containing silicon (Si) and oxygen (O), that is, a silicon oxide. For example, the surface of the concave portion can include a Si-containing oxide film such as a silicon oxide film (SiO film), a silicon oxynitride film (SiON film), a silicon oxycarbonitride (SiOCN film film), and a silicon oxycarbide film (SiOC film). The surface of the concave portion may also include a silicon film (Si film), a silicon nitride film (SiN film), a silicon carbonitride film (SiCN film), a silicon carbide film (SiC film), a silicon boron nitride film (SiBN film), a silicon boron carbonitride film (SiBCN film), a SiON film, a SiOCN film, SiOC film and the like on a surface of which a natural oxide film is formed, that is a Si-containing film on a surface of which a natural oxide film is formed. At least a part of the surface of the concave portion is a target of the etching processing to be described later.

### (Pressure Regulation and Temperature Regulation)

After the boat load is finished, the inside of the processing chamber 201, that is, a space in which the wafer 200 is present is vacuum-exhausted (decompression-exhausted) by the vacuum pump 246 so as to achieve a desired pressure (vacuum degree). At that time, the pressure in the processing chamber 201 is measured by the pressure sensor 245, and the APC valve 244 is feedback-controlled on the basis of information of the measured pressure. The heater 207 heats in such a manner that temperature of the wafer 200 in the processing chamber 201 reaches desired processing temperature. At that time, on the basis of the temperature information detected by the temperature sensor 263, the degree of energization to the heater 207 is feedback-controlled in such a manner that a desired temperature distribution is obtained in the processing chamber 201. The rotating mechanism 267 starts to rotate the wafer 200. The exhaust in the processing chamber 201, the heating and rotation of the wafer 200 continue at least until the processing on the wafer 200 is finished.

### (Step A)

Thereafter, the modifying agent including the reducing agent is excited and supplied to the wafer 200 including the concave portion, the surface of which includes the oxygen-containing substance.

Specifically, the valve 243a is opened to allow the modifying agent (reducing agent) to flow into the gas supply pipe 232a. The modifying agent a flow rate of which is regulated by the MFC 241a is excited into a plasma state by the RPU 300, supplied into the processing chamber 201 via the nozzle 249a, and discharged from the exhaust port 231a. At that time, the modifying agent excited into a plasma state is supplied from the lateral side of the wafer 200 to the wafer 200 (modifying agent supply). In this manner, an excited species generated by exciting the modifying agent, that is, the excited species (activated species) generated by exciting the modifying agent into a plasma state is supplied to the wafer 200. At that time, the valves 243f to 243h may be opened to supply the inert gas into the processing chamber 201 via the nozzles 249a to 249c, respectively.

By exciting the modifying agent into a plasma state and supplying the same to the wafer 200 under processing conditions to be described later, the excited species generated by exciting the modifying agent into a plasma state and the surface of the upper portion of the concave portion are allowed to react with each other, and the oxygen concentration (oxygen ratio, oxygen content) on the surface of the upper portion of the concave portion can be changed as illustrated in FIG. 4B. A portion of the surface of the concave portion in which the oxygen concentration is changed by the supply of the excited modifying agent is also referred to as a modified portion.

When the modifying agent is excited and supplied to the wafer 200 under the processing conditions to be described later, at least a part of the excited species supplied to the wafer 200 can be consumed by the reaction with the surface of the upper portion of the concave portion to be deactivated. As a result, in the portion other than the upper portion of the concave portion, that is, at least any one of the central portion, the lower portion, or the bottom portion of the concave portion, a supply amount of the excited species per unit surface area can be reduced as compared with that in the upper portion of the concave portion. Therefore, in the portion other than the upper portion of the concave portion, the reaction between the excited species and the surface can be suppressed as compared with the upper portion of the concave portion, and an amount of change in the oxygen concentration on the surface can be reduced. As a result, at step A, the oxygen concentration on the surface of the upper portion of the concave portion can be made different from the oxygen concentration on the surface of the portion other than the upper portion of the concave portion. This phenomenon can be especially remarkably obtained in a case where the modifying agent is excited into a plasma state and supplied to the wafer 200, that is, in a case where the excited species (activated species) generated by exciting the modifying agent into a plasma state is supplied.

In the present embodiment, by exciting the reducing agent as the modifying agent into a plasma state and supplying the same to the wafer 200 under the processing conditions to be described later, a reduction reaction of the surface by the excited species can proceed in the upper portion of the concave portion, and the oxygen concentration on the surface can be reduced. In the portion other than the upper portion of the concave portion, the supply amount of the excited species per unit area can be reduced, the reduction reaction on the surface by the excited species can be suppressed, and a reduction amount of the oxygen concentration on the surface can be reduced. As a result, at step A, the oxygen concentration on the surface of the upper portion of the concave portion can be made lower than the oxygen concentration on the surface of the portion other than the upper portion of the concave portion.

The processing conditions when exciting the modifying agent (reducing agent) into a plasma state and supplying the same at step A are exemplified as follows:
processing temperature: room temperature (25° C.) to 400° C., preferably 50 to 250° C.;
processing pressure: 1 to 10000 Pa, preferably 50 to 1000 Pa;
processing time: 1 to 600 seconds, preferably 5 to 300 seconds;
modifying agent supply flow rate: 0.01 to 10 slm, preferably 0.1 to 5 slm;
inert gas supply flow rate (per gas supply pipe): 0 to 20 slm;
RF power: 1 to 10000 W, preferably 100 to 5000 W; and
RF frequency: 13.5 MHz or 27 MHZ.

In this specification, an expression of a numerical range such as “25 to 400° C.” means that a lower limit value and an upper limit value are included in the range. Therefore, for example, “25 to 400° C.” means “equal to or higher than 25° C. and equal to lower than 400° C.”. The same applies to other numerical ranges. In this specification, the processing temperature means the temperature of the wafer 200 or the temperature in the processing chamber 201, and the processing pressure means the pressure in the processing chamber 201. The processing time means a time in which the processing is continued. In a case where 0 slm is included in the supply flow rate, 0 slm means a case where the substance (gas) is not supplied. The RF power is high-frequency power applied to an electrode of the RPU 300 when the modifying agent is plasma-excited, and the RF frequency is a frequency in the above-described RF power. The same applies to the following description.

After the oxygen concentration on the surface of the upper portion of the concave portion is changed (reduced in the present embodiment), the valve 243a is closed to stop supplying the modifying agent into the processing chamber 201. The inside of the processing chamber 201 is vacuum-exhausted to remove the gaseous substance and the like remaining in the processing chamber 201 from the inside of the processing chamber 201. At that time, the valves 243f to 243h are opened to supply the inert gas into the processing chamber 201 via the nozzles 249a to 249c. The inert gas supplied by the nozzles 249a to 249c acts as the purge gas, so that the inside of the processing chamber 201 is purged (purge).

The processing conditions when purging at step A are exemplified as follows:
processing pressure: 1 to 30 Pa;
processing time: 1 to 120 seconds, preferably 1 to 60 seconds; and
inert gas supply flow rate (per gas supply pipe): 0.5 to 20 slm. The processing temperature when purging at this step is preferably similar to the processing temperature when supplying the modifying agent.

A hydrogen-containing gas such as a hydrogen (H₂) gas and a deuterium-containing gas such as a deuterium (D₂) gas can be used as the modifying agent (reducing agent). One or more of them may be used as the modifying agent. Processing of exciting the hydrogen-containing gas into a plasma state and supplying the same to the wafer 200 is also referred to as hydrogen-containing plasma processing, and an activated species (H₂^{*}, H^{*} and the like) generated at that time is also referred to as a hydrogen-containing activated species (hydrogen-containing radical). Processing of exciting the deuterium-containing gas into a plasma state and supplying the same to the wafer 200 is also referred to as deuterium-containing plasma processing, and an activated species (D₂^{*}, D^{*} and the like) generated at that time is also referred to as a deuterium-containing activated species (deuterium-containing radical).

As the inert gas, a nitrogen (N₂) gas or a rare gas such as an argon (Ar) gas, a helium (He) gas, a neon (Ne) gas, and a xenon (Xe) gas can be used. One or more of these gases can be used as the inert gas. The same applies to each step described later.

### (Step B)

After step A is finished, the etching agent is supplied to the wafer 200 in which the oxygen concentration on the surface of the upper portion of the concave portion has been changed (reduced in the present embodiment).

Specifically, the valve 243b is opened to allow the etching agent to flow into the gas supply pipe 232b. The etching agent a flow rate of which is regulated by the MFC 241b is supplied into the processing chamber 201 via the nozzle 249b and discharged from the exhaust port 231a. At that time, the etching agent is supplied from the lateral side of the wafer 200 to the wafer 200 (etching agent supply). At that time, the valves 243f to 243h may be opened to supply the inert gas into the processing chamber 201 via the nozzles 249a to 249c, respectively.

By supplying the etching agent to the wafer 200 under the processing conditions to be described later, at least a part of the surface of the concave portion can be etched as illustrated in FIG. 4C.

Herein, at least a part of the etching agent supplied to the wafer 200 is consumed by etching reaction on the surface of the upper portion of the concave portion.

In a case of performing step B without performing step A, in the portion other than the upper portion of the concave portion, that is, at least any one of the central portion, the lower portion, or the bottom portion of the concave portion, the supply amount of the etching agent per unit surface area tends to be reduced as compared with that in the upper portion of the concave portion. In this case, there is a tendency that an etching rate on the surface of the upper portion of the concave portion is larger than the etching rate on the surface of the portion other than the upper portion of the concave portion, that is, the surface on the upper side of the concave portion is easily etched with respect to the surface on the lower side of the concave portion, and conformal etching of the surface of the concave portion is difficult.

In contrast, in the present embodiment, step A is performed before step B is performed. Therefore, the oxygen concentration on the surface of the upper portion of the concave portion to be etched can be made different from the oxygen concentration on the surface of the portion other than the upper portion of the concave portion. Specifically, the oxygen concentration on the surface of the upper portion of the concave portion to be etched can be made lower than the oxygen concentration on the surface of the portion other than the upper portion of the concave portion. At step B, by appropriately selecting a substance used as the etching agent, a processing procedure, and the processing conditions, a situation in which a target the oxygen concentration of which is high can be easily etched and a target the oxygen concentration of which is low is etched with difficulty is created (predetermined etching selectivity is exhibited). This makes it possible to selectively lower the etching rate on the surface of the upper portion of the concave portion while suppressing a reduction in the etching rate on the surface of the portion other than the upper portion of the concave portion when etching the surface of the concave portion. That is, the etching rate on the surface of the upper portion of the concave portion can be regulated to approach the etching rate on the surface of the portion other than the upper portion of the concave portion.

As a result, in the present embodiment, the etching rate of the surface on the upper side of the concave portion with respect to the surface on the lower side of the concave portion can be reduced, and the above-described tendency that the surface on the upper side of the concave portion is easily etched with respect to the surface on the lower side of the concave portion can be cancelled. Therefore, an etching amount of the surface of the concave portion can be made uniform, and as illustrated in FIG. 4C, the surface of the concave portion can be conformally etched.

Note that, in the present embodiment,
in a case where a ratio of an etching rate on the surface of the upper portion of the concave portion to an etching rate on the surface of the lower portion of the concave portion by the etching agent in a case where step A is not performed is set to ERRA, and
a ratio of an etching rate on the surface of the upper portion of the concave portion to an etching rate on the surface of the lower portion of the concave portion by the etching agent in a case of performing step A is set to ERRB,
a ratio of ERRB to ERRA (ERRB/ERRA) can be set to 0.01 or larger and smaller than 1, preferably 0.02 or larger and 0.9 or smaller, and more preferably 0.05 or larger and 0.8 or smaller.

When performing step B, all of the modified portion may be removed, or a part of the modified portion may be left as illustrated in FIG. 4C. That is, the etching may be stopped in a state in which the oxygen concentration on the surface of the upper portion of the concave portion is equivalent to the oxygen concentration on the surface of the portion other than the upper portion of the concave portion, or the etching may be stopped in a state in which the oxygen concentration on the surface of the upper portion of the concave portion remains different from the oxygen concentration on the surface of the portion other than the upper portion of the concave portion (in the present embodiment, the oxygen concentration on the surface of the upper portion of the concave portion remains reduced).

The processing conditions when supplying the etching agent at step B are exemplified as follows:
processing temperature: room temperature (25° C.) to 400° C., preferably 50 to 250° C.;
processing pressure: 1 to 13332 Pa, preferably 1 to 1333 Pa;
processing time: 1 second to 120 minutes, preferably 1 to 60 minutes;
etching agent supply flow rate: 0.001 to 2 slm; and
inert gas supply flow rate (per gas supply pipe): 0 to 20 slm.

After the etching of at least a part of the surface of the concave portion is finished, the valve 243b is closed, and the supply of the etching agent into the processing chamber 201 is stopped. By the processing procedure and the processing conditions similar to those in the purge at step A, the gaseous substance and the like remaining in the processing chamber 201 is removed from the inside of the processing chamber 201 (purge). The processing temperature when performing the purge at this step is preferably similar to the processing temperature when supplying the etching agent.

As the etching agent, a substance containing fluorine (F), that is, a fluorine-based substance can be used, and for example, a fluorine-containing gas can be used. As the fluorine-containing gas, for example, a fluorine-containing gas such as a fluorine (F₂) gas, a hydrogen fluoride (HF) gas, a chlorine trifluoride (ClF₃) gas, a chlorine fluoride (ClF) gas, a nitrogen fluoride (NF₃) gas, and a nitrosyl fluoride (FNO) gas, a hydrogen and fluorine-containing gas, a chlorine and fluorine-containing gas, a nitrogen and fluorine-containing gas, a fluorine, nitrogen, and oxygen-containing gas and the like can be used. In this manner, as the etching agent, for example, a fluorine-containing substance, a hydrogen and fluorine-containing substance, a chlorine and fluorine-containing substance, a nitrogen and fluorine-containing substance, a fluorine, nitrogen, and oxygen-containing substance and the like can be used. That is, as the etching agent, for example, a halogen simple substance, hydrogen halide, an interhalogen compound, nitrogen halide, nitrosyl halide and the like can be used. One or more of them can be used as the etching agent.

### (Predetermined Number of Times of Performance)

By performing the above-described cycle including step A and step B, that is, the cycle in which each step is performed in this order non simultaneously a predetermined number of times (n times: n is an integer of 1 or 2 or larger), it is possible to perform the etching processing of conformally etching the surface of the concave portion by a predetermined amount. The cycle described above is preferably repeated a plurality of times. That is, it is preferable that a thickness of the surface of the concave portion etched per cycle is made thinner than a desired etching thickness (predetermined amount), and the above-described cycle is repeated a plurality of times until the etching thickness of the surface of the concave portion reaches a desired thickness (depth). In this case, at step A of a first cycle, a part of the surface of the concave portion is modified as illustrated in FIG. 4B, and at step B of the first cycle, a part of the surface of the concave portion is etched as illustrated in FIG. 4C. At step A of second and subsequent cycles, a part of the surface of the concave portion after the etching is further modified as illustrated in FIG. 4D, and at step B of second and subsequent cycles, a part of the surface of the concave portion after the etching is further etched as illustrated in FIG. 4E. By repeating the above-described cycle a plurality of number of times, it is also possible to remove all of the oxygen-containing substances forming the surface of the concave portion.

### (Step C)

As described above, the oxygen concentration on the surface of the upper portion of the concave portion changed at step A is sometimes maintained even after step B is performed, and in that case, after the etching processing (after the above-described cycle is performed a predetermined number of times), the oxygen concentration on the surface of the upper portion of the concave portion is different from the oxygen concentration on the surface of the portion other than the upper portion of the concave portion in some cases. Therefore, in the present embodiment, step C of supplying the oxidizing agent to the wafer 200 is performed after the etching processing. Hereinafter, a case where the catalyst is supplied to the wafer 200 together with the oxidizing agent at step C will be described. At step C, the supply of the catalyst can also be omitted.

Specifically, the valves 243d and 243e are opened to allow the oxidizing agent and the catalyst to flow into the gas supply pipes 232d and 232e, respectively. The oxidizing agent and the catalyst of which flow rates are regulated by the MFCs 241d and 241e, respectively, are supplied into the processing chamber 201 via the gas supply pipes 232a and 232b and the nozzles 249a and 249b, respectively, mixed in the processing chamber 201, and discharged from the exhaust port 231a. At that time, the oxidizing agent and the catalyst are supplied from the lateral side of the wafer 200 to the wafer 200 (oxidizing agent and catalyst supply). At that time, the valves 243f to 243h may be opened to supply the inert gas into the processing chamber 201 via the nozzles 249a to 249c, respectively.

By supplying the oxidizing agent to the wafer 200 under the processing conditions to be described later, the surface of the concave portion after the etching processing can be oxidized as illustrated in FIG. 4F. Therefore, the oxygen concentration (oxygen ratio, oxygen content) on the surface of the concave portion can be made uniform, and the oxygen concentration on the surface of the upper portion of the concave portion can be made equivalent to the oxygen concentration on the surface of the portion other than the upper portion of the concave portion. Out of the surface of the concave portion, a portion oxidized by the supply of the oxidizing agent, that is, a portion in which the oxygen concentration is made uniform is also referred to as an oxidized portion.

The processing conditions when supplying the oxidizing agent at step C are exemplified as follows:
processing temperature: room temperature (25° C.) to 400° C., preferably 50 to 250° C.;
processing pressure: 1 to 10000 Pa, preferably 50 to 1000 Pa;

processing time: 1 to 600 seconds, preferably 5 to 300 seconds;
oxidizing agent supply flow rate: 0.01 to 10 slm, preferably 0.1 to 5 slm;
catalyst supply flow rate: 0 to 10 slm, preferably 0 to 5 slm; and
inert gas supply flow rate (per gas supply pipe): 0 to 20 slm.

After the oxygen concentration on the surface of the concave portion is uniformized, the valves 243d and 243e are closed to stop supplying the oxidizing agent and catalyst into the processing chamber 201. By the processing procedure and the processing conditions similar to those in the purge at step A, the gaseous substance and the like remaining in the processing chamber 201 is removed from the inside of the processing chamber 201 (purge). The processing temperature when purging at this step is preferably similar to the processing temperature when supplying the oxidizing agent.

As the oxidizing agent, an oxygen-containing gas such as an oxygen (O₂) gas, an ozone (O₃) gas, O₂ gas+H₂ gas, O₂ gas+D₂ gas, O₃ gas+H₂ gas, O₃ gas+D₂ gas, a hydrogen peroxide (H₂O₂) gas, a water vapor (H₂O) gas, a nitrous oxide (N₂O) gas, a nitric oxide (NO) gas, a nitrogen dioxide (NO₂) gas, a carbon dioxide gas (CO₂), and a carbon oxide (CO) gas can be used. One or more of them can be used as the oxidizing agent. Herein, the description of two gases such as “O₂ gas+H₂ gas” means a mixed gas of O₂ gas and H₂ gas. In a case of supplying the mixed gas, the two gases may be mixed (premixed) in the supply pipe and then supplied into the processing chamber 201, or the two gases may be separately supplied into the processing chamber 201 from different supply pipes and mixed (post-mixed) in the processing chamber 201.

As the catalyst, for example, an amine-based gas (amine-based substance) containing carbon (C), nitrogen (N), and hydrogen (H) can be used. As the amine-based gas (amine-based substance), a chain amine-based gas (chain amine-based substance) or a cyclic amine-based gas (cyclic amine-based substance) can be used. As the catalyst, for example, chain amines such as triethylamine ((C₂H₅)₃N), diethylamine ((C₂H₅)₂NH), monoethylamine ((C₂H₅)NH₂), trimethylamine ((CH₃)₃N), dimethylamine ((CH₃)₂NH), and monomethylamine ((CH₃)NH₂) can be used. As the catalyst, for example, cyclic amines such as aminopyridine (C₅H₆N₂), pyridine (C₅H₅N), picoline (C₆H₇N), lutidine (C₇H₉N), pyrimidine (C₄H₄N₂), quinoline (C₉H₇N), piperazine (C₄H₁₀N₂), piperidine (C₅H₁₁N), and aniline (C₆H₇N) can be used. One or more of them can be used as the catalyst.

Note that, as described above, in a case where it is not necessary to uniformize the oxygen concentration on the surface of the concave portion after the etching processing, step C can be omitted.

### (After-Purge and Atmospheric Pressure Restoration)

After step C is finished, the inert gas as the purge gas is supplied from each of the nozzles 249a to 249c into the processing chamber 201 and is discharged from the exhaust port 231a. Therefore, the inside of the processing chamber 201 is purged, and a gas, a reaction by-product and the like remaining in the processing chamber 201 are removed from the inside of the processing chamber 201 (after-purge). Thereafter, the atmosphere in the processing chamber 201 is replaced with the inert gas (inert gas replacement), so that the pressure in the processing chamber 201 is restored to a normal pressure (atmospheric pressure restoration).

### (Boat Unload and Wafer Discharge)

After that, the boat elevator 115 lowers the seal cap 219, and the lower end of the manifold 209 is opened. The processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed by the shutter 219s via the O-ring 220c (shutter close). After being unloaded to the outside of the reaction tube 203, the processed wafer 200 is taken out from the boat 217 (wafer discharge).

Steps A, B, and C are preferably performed in the same processing chamber (in-situ). When a series of processing is performed in-situ, the wafer 200 is not exposed to the atmosphere in the middle, and the processing can be consistently performed while the wafer 200 is placed under vacuum, and stable processing can be performed.

### (3) Effects by Present Embodiment

According to the present embodiment, one or a plurality of effects described below can be obtained.
(a) By performing the cycle including steps A and B a plurality of number times, when etching the surface of the concave portion included in the substrate, the etching rate of the surface on the upper side of the concave portion with respect to the surface on the lower side of the concave portion can be reduced, and the tendency that the surface on the upper side of the concave portion is easily etched with respect to the surface on the lower side of the concave portion can be cancelled. Therefore, an etching amount of the surface of the concave portion can be made uniform, and as a result, the surface of the concave portion can be conformally etched. That is, the surface of the concave portion can be etched with high conformality.
(b) By supplying the excited species generated by exciting the modifying agent to the substrate at step A, the excited species generated by exciting the modifying agent can be deactivated in the upper portion of the concave portion, and the oxygen concentration on the surface of the upper portion of the concave portion can be selectively changed.

At step A, in a case where the excited species generated by exciting the modifying agent into a plasma state is supplied to the substrate, the activated species can be generated as the excited species, a degree of deactivation of the excited species in the upper portion of the concave portion can be effectively increased, and the oxygen concentration on the surface of the upper portion of the concave portion can be selectively changed effectively.
(c) Since the modifying agent includes the reducing agent, it is possible to effectively produce the above-described action, and it is possible to selectively change the oxygen concentration on the surface of the upper portion of the concave portion effectively.

Because the modifying agent includes at least one selected from the group of the hydrogen-containing gas and the deuterium-containing gas, that is, by performing at least one selected from the group of the hydrogen-containing plasma processing and the deuterium plasma processing at step A, it is possible to more effectively produce the above-described action, and it is possible to selectively change the oxygen concentration on the surface of the upper portion of the concave portion more effectively.
(d) At step A, by making the oxygen concentration on the surface of the upper portion of the concave portion different from the oxygen concentration on the surface of the portion other than the upper portion of the concave portion, the etching rate of the surface of the upper portion of the concave portion with respect to the surface of the portion other than the upper portion of the concave portion can be reduced, and the tendency that the surface of the upper portion of the concave portion is easily etched with respect to the surface of the portion other than the upper portion of the concave portion can be cancelled. Therefore, the etching amount of the surface of the concave portion can be made uniform effectively, and as a result, the surface of the concave portion can be conformally etched effectively.
(e) Because the surface of the concave portion includes the oxide described above, the above-described action can be effectively produced.
(f) Because the etching agent contains fluorine, the above-described action can be effectively produced. In a case where the etching agent contains fluorine and hydrogen, the above-described action can be more effectively produced.
(g) By setting ERRB/ERRA to 0.01 or larger and smaller than 1, it is possible to conformally etch the surface of the concave portion.
(a) Herein, when ERRB/ERRA is 0.01 or smaller, an action of lowering the etching rate of the surface on the upper side of the concave portion with respect to the surface on the lower side of the concave portion is excessive, the surface on the lower side of the concave portion is excessively etched with respect to the surface on the upper side of the concave portion, and it is not possible to conformally etch the surface of the concave portion in some cases. As in the present embodiment, by setting ERRB/ERRA to 0.01 or lager, the action of lowering the etching rate of the surface on the upper side of the concave portion with respect to the surface on the lower side of the concave portion can be made appropriate, and the surface of the concave portion can be conformally etched. By setting ERRB/ERRA to 0.02 or larger, this effect can be enhanced, and by setting ERRB/ERRA to 0.05 or larger, this effect can be further enhanced.

When ERRB/ERRA is 1 or larger, the tendency that the surface on the upper side of the concave portion is easily etched with respect to the surface on the lower side of the concave portion cannot be cancelled, and the surface of the concave portion cannot be conformally etched in some cases. As in the present embodiment, by setting ERRB/ERRA to smaller than 1, the tendency that the surface on the upper side of the concave portion is easily etched with respect to the surface on the lower side of the concave portion can be cancelled, and the surface of the concave portion can be conformally etched. By setting ERRB/ERRA to 0.9 or smaller, this effect can be enhanced, and by setting ERRB/ERRA to 0.8 or smaller, this effect can be further enhanced.
(h) By performing step C after the etching processing in the concave portion, the oxygen concentration on the surface of the concave portion after the etching processing can be made uniform, and the oxygen concentration on the surface of the upper portion of the concave portion can be made equivalent to the oxygen concentration on the surface of the portion other than the upper portion of the concave portion. As a result, composition (constituent element concentration, molecular structure, film quality) of the surface of the concave portion after the etching processing can be made uniform.
(i) The above-described effects can be similarly obtained even in a case where a predetermined substance is optionally selected from the various modifying agents, various etching agents, various oxidizing agents, various catalysts, and various inert gases described above to be used.

### Second embodiment of Present Disclosure

The present embodiment is different from the first embodiment described above in that, at step A, an oxygen concentration on a surface of an upper portion of a concave portion is changed so as to be higher than an oxygen concentration on a surface of a portion other than the upper portion of the concave portion by using a modifying agent including an oxidizing agent, so that the oxygen concentrations on the respective surfaces are made different from each other. The present embodiment is different from the first embodiment described above in that an etching agent used at step B contains a first substance and a second substance, and at step B, the first substance and the second substance are alternately supplied to a wafer 200. Hereinafter, an example of a processing sequence of the present embodiment will be described. Hereinafter, a point different from that in the first embodiment will be mainly described.

As in the first embodiment, wafer charge, boat load, pressure regulation, and temperature regulation are performed.

### (Step A)

Thereafter, the modifying agent including the oxidizing agent is excited and supplied to the wafer 200 including the concave portion, the surface of which includes an oxygen-containing substance.

Specifically, a valve 243d is opened to allow the modifying agent (oxidizing agent) to flow into a gas supply pipe 232d. The modifying agent a flow rate of which is regulated by an MFC 241d is excited into a plasma state by an RPU 300, supplied into a processing chamber 201 via a nozzle 249a, and discharged from an exhaust port 231a. At that time, the modifying agent excited into a plasma state is supplied from the lateral side of the wafer 200 to the wafer 200 (modifying agent supply). In this manner, an excited species generated by exciting the modifying agent, that is, the excited species (activated species) generated by exciting the modifying agent into a plasma state is supplied to the wafer 200. At that time, the valves 243f to 243h may be opened to supply the inert gas into the processing chamber 201 via the nozzles 249a to 249c, respectively.

By exciting the oxidizing agent as the modifying agent into a plasma state and supplying the same to the wafer 200 under processing conditions to be described later, the oxygen concentration (oxygen ratio, oxygen content) on the surface of the upper portion of the concave portion can be changed, and the oxygen concentration on the surface of the upper portion of the concave portion can be made different from the oxygen concentration on the surface of the portion other than the upper portion of the concave portion. That is, in the upper portion of the concave portion, an oxidizing reaction of the surface by the excited species can proceed to increase the oxygen concentration on the surface. At that time, at least a part of the excited species can be consumed by a reaction with the surface of the upper portion of the concave portion to be deactivated, and in the portion other than the upper portion of the concave portion, a supply amount of the excited species per unit surface area can be reduced as compared with that in the upper portion of the concave portion. Therefore, in the portion other than the upper portion of the concave portion, the oxidizing reaction of the surface by the excited species can be suppressed, and an amount of increase in the oxygen concentration on the surface can be reduced. As a result, at step A, the oxygen concentration on the surface of the upper portion of the concave portion can be made higher than the oxygen concentration on the surface of the portion other than the upper portion of the concave portion.

The processing conditions when the modifying agent (oxidizing agent) is excited into a plasma state and supplied at step A can be similar to the processing conditions when the modifying agent (reducing agent) is excited into a plasma state and supplied at step A of the first embodiment.

After the oxygen concentration on the surface of the upper portion of the concave portion is changed (increased in the present embodiment), the valve 243d is closed to stop supplying the modifying agent into the processing chamber 201. By the processing procedure and processing conditions similar to those in the purge at step A of the first embodiment, a gaseous substance and the like remaining in the processing chamber 201 is removed from the inside of the processing chamber 201 (purge).

As the modifying agent (oxidizing agent), the oxidizing agent described at step C of the first embodiment, that is, an oxygen-containing gas can be used. Processing of exciting the oxygen-containing gas into a plasma state and supplying the same to the wafer 200 is also referred to as oxygen-containing plasma processing, and an activated species (O₂^{*}, O^{*} and the like) generated at that time is also referred to as an oxygen-containing activated species (oxygen-containing radical).

(Step B)

After step A is finished, next steps B1 and B2 are performed, and the first substance and the second substance are alternately supplied as the etching agent to the wafer 200 in which the oxygen concentration on the surface of the upper portion of the concave portion has been changed (reduced in the present embodiment).

### [Step B1]

At step B1, the first substance as the etching agent is supplied from an etching agent (first substance) supply system to the wafer 200. The processing procedure at step B1 can be similar to the processing procedure at step B in the first embodiment.

The processing condition when supplying the etching agent (first substance) at step B1 is exemplified as follows:
processing temperature: room temperature (25° C.) to 400° C., preferably 50 to 250° C.;
processing pressure: 1 to 13332 Pa, preferably 1 to 1333 Pa;
processing time: 1 second to 120 minutes, preferably 1 to 60 minutes;
first substance supply flow rate: 0.001 to 2 slm; and
inert gas supply flow rate (per gas supply pipe): 0 to 20 slm.

After a predetermined time has elapsed, a valve 243b is closed to stop supplying the first substance into the processing chamber 201. By the processing procedure and processing conditions similar to those in the purge at step A of the first embodiment, a gaseous substance and the like remaining in the processing chamber 201 is removed from the inside of the processing chamber 201 (purge). The processing temperature when purging at this step is preferably similar to the processing temperature when supplying the first substance.

As the first substance, various fluorine-based substances described at step B of the first embodiment can be used. One or more of them can be used as the first substance.

### (Step B2)

At step B2, the second substance as the etching agent is supplied from an etching agent (second substance) supply system to the wafer 200.

Specifically, a valve 243c is opened to allow the second substance to flow into a gas supply pipe 232c. The second substance a flow rate of which is regulated by an MFC 241c is supplied into the processing chamber 201 via the nozzle 249c, and discharged from the exhaust port 231a. At that time, the second substance is supplied from the lateral side of the wafer 200 to the wafer 200 (second substance supply). At that time, the valves 243f to 243h may be opened to supply the inert gas into the processing chamber 201 via the nozzles 249a to 249c, respectively.

The processing conditions when supplying the etching agent (second substance) at step B2 are exemplified as follows:
processing temperature: room temperature (25° C.) to 400° C., preferably 50 to 250° C.;
processing pressure: 1 to 13332 Pa, preferably 1 to 1333 Pa;
processing time: 1 second to 120 minutes, preferably 1 to 60 minutes;
second substance supply flow rate: 0.001 to 2 slm; and
inert gas supply flow rate (per gas supply pipe): 0 to 20 slm.

After a predetermined time has elapsed, the valve 243c is closed to stop supplying the second substance into the processing chamber 201. By the processing procedure and processing conditions similar to those in the purge at step A of the first embodiment, a gaseous substance and the like remaining in the processing chamber 201 is removed from the inside of the processing chamber 201 (purge). The processing temperature when purging at this step is preferably similar to the processing temperature when supplying the second substance.

As the second substance, various fluorine-based substances described at step B of the first embodiment can be used. As the second substance, an ammonia (NH₃) gas, an H₂ gas, an O₂ gas, an NO gas, an O₃ gas, an H₂O gas, an isopropyl alcohol ((CH₃)₂CHOH) gas, a methanol (CH₃OH) gas, a boron trichloride (BCl₃) gas, a chlorine (Cl₂) gas, a hydrogen chloride (HCl) gas and the like can be used. One or more of them can be used as the second substance.

For example, in a case where an F₂ gas is used as the first substance, an HF gas, a ClF₃ gas, a ClF gas, an NF₃ gas, an FNO gas, an NH₃ gas, an H₂ gas, an O₂ gas, an NO gas, an O₃ gas, an H₂O gas, a (CH₃)₂CHOH gas, a CH₃OH gas, a BCl₃ gas, a Cl₂ gas, an HCl gas and the like can be used as the second substance. For example, in a case where an HF gas is used as the first substance, an F₂ gas, an ClF₃ gas, a ClF gas, an NF₃ gas, an FNO gas, an NH₃ gas, an H₂ gas, an O₂ gas, an NO gas, an O₃ gas, an H₂O gas, a (CH₃)₂CHOH gas, a CH₃OH gas, a BCl₃ gas, a Cl₂ gas, an HCl gas and the like can be used as the second substance. As described above, at least one selected from the group of the first substance and the second substance preferably contains F, and both the first substance and the second substance may contain F.

### Alternate Performance

By alternately performing step B1 and step B2 described above a predetermined number of times (m times: m is an integer of 1 or 2 or larger), at least a part of the surface of the concave portion can be etched.

In the present embodiment also, in a case of performing step B without performing step A, there is a tendency that, in the portion other than the upper portion of the concave portion, the supply amount of the etching agent per unit surface area is easily reduced as compared with that in the upper portion of the concave portion, and conformal etching of the surface of the concave portion is difficult.

In contrast, in the present embodiment, step A is performed before step B is performed. Therefore, the oxygen concentration on the surface of the upper portion of the concave portion to be etched can be made different from the oxygen concentration on the surface of the portion other than the upper portion of the concave portion. Specifically, the oxygen concentration on the surface of the upper portion of the concave portion to be etched can be made higher than the oxygen concentration on the surface of the portion other than the upper portion of the concave portion. At step B, by appropriately selecting a substance used as the etching agent, a processing procedure, and the processing conditions, a situation in which a target the oxygen concentration of which is high is etched with difficulty and a target the oxygen concentration of which is low is easily etched is created (predetermined etching selectivity is exhibited). This makes it possible to selectively lower the etching rate on the surface of the upper portion of the concave portion while suppressing a reduction in the etching rate on the surface of the portion other than the upper portion of the concave portion when etching the surface of the concave portion. That is, the etching rate on the surface of the upper portion of the concave portion can be regulated to approach the etching rate on the surface of the portion other than the upper portion of the concave portion.

As a result, in the present embodiment also, the etching rate of the surface on the upper side of the concave portion with respect to the surface on the lower side of the concave portion can be reduced, and the above-described tendency that the surface on the upper side of the concave portion is easily etched with respect to the surface on the lower side of the concave portion can be cancelled. Therefore, an etching amount of the surface of the concave portion can be made uniform, and the surface of the concave portion can be conformally etched. In this embodiment also, the ratio of ERRB to ERRA (ERRB/ERRA) can be set to 0.01 or larger and smaller than 1, preferably 0.02 or larger and 0.9 or smaller, and more preferably 0.05 or larger and 0.8 or smaller.

In this embodiment also, when performing step B, all of the modified portion may be removed, or a part of the modified portion may be left.

### (Predetermined Number of Times of Performance)

By performing the above-described cycle including step A and step B a predetermined number of times (n times: n is an integer of 1 or 2 or larger), it is possible to etch the surface of the concave portion conformally by a predetermined amount as in the first embodiment.

Thereafter, as in the first embodiment, step C is performed as necessary, and after purge, atmospheric pressure restoration, boat unload, and wafer discharge are further performed.

In the present embodiment also, effects similar to those in the first embodiment can be obtained. That is, in the present embodiment also, by performing steps A and B described above a predetermined of number times, when etching the surface of the concave portion included in the substrate, the tendency that the surface on the upper side of the concave portion is easily etched with respect to the surface on the lower side of the concave portion can be cancelled.

In the present embodiment, since the modifying agent includes the oxidizing agent, it is possible to effectively produce the above-described action, and it is possible to selectively change the oxygen concentration on the surface of the upper portion of the concave portion effectively.

In the present embodiment, since the modifying agent includes the oxygen-containing gas, that is, by performing the oxygen-containing plasma processing at step A, the above-described action can be effectively produced.

In the present embodiment, since the etching agent includes the first substance and the second substance, and at least one selected from the group of the first substance and the second substance contains fluorine, the above-described action can be effectively produced.

At step B of the present embodiment, by alternately supplying the first substance and the second substance to the substrate, the above-described action can be more effectively produced.

### Other Embodiments of Present Disclosure

The embodiments of the present disclosure have been specifically described above. Note that, the present disclosure is not limited to the embodiments described above, and can be variously modified without departing from the gist thereof.

For example, in the first embodiment, at step A, the inert gas as the modifying agent can be excited into a plasma state and supplied.

The processing condition when exciting the modifying agent (inert gas) into a plasma state and supplying the same at step A is exemplified as follows:
modifying agent (inert gas) supply flow rate: 0.01 to 10 slm, preferably 0.1 to 5 slm. Other processing conditions can be similar to the processing conditions at step A in the first embodiment.

As the modifying agent (inert gas), various inert gases described in the embodiments described above can be used. Processing of exciting the inert gas into a plasma state and supplying the same to the wafer 200 is also referred to as inert gas plasma processing. Processing of exciting a rare gas among the inert gases into a plasma state and supplying the same is also referred to as rare gas plasma processing. The activated species (N₂^{*}, N^{*}, Ar^{*}, He^{*}, Ne^{*}, Xe^{*} or the like) generated at that time is also referred to as an inert gas activated species and a rare gas activated species (inert gas radical, rare gas radical).

In this embodiment also, the tendency that the surface on the upper side of the concave portion is easily etched with respect to the surface on the lower side of the concave portion can be cancelled, and the effect similar to that in the embodiments described above can be obtained.

For example, in the second embodiment, at step A, the modifying agent including the oxidizing agent can be thermally excited and supplied in a non-plasma atmosphere. At that time, a catalyst can also be supplied together with the oxidizing agent. The supply of the catalyst can be omitted.

The processing conditions when thermally exciting the modifying agent (oxidizing agent) and supplying the same at step A are exemplified as follows:
processing temperature: room temperature (25° C.) to 600° C., preferably 50 to 400° C.;
processing pressure: 1 to 10000 Pa, preferably 50 to 3000 Pa;
processing time: 1 to 600 seconds, preferably 5 to 300 seconds;
modifying agent supply flow rate: 0.01 to 10 slm, preferably 0.1 to 5 slm;
catalyst supply flow rate: 0 to 10 slm, preferably 0 to 5 slm; and
inert gas supply flow rate (per gas supply pipe): 0 to 20 slm.

As the modifying agent (oxidizing agent) and the catalyst, the oxidizing agent (oxygen-containing gas) and the catalyst described in the embodiments described above can be used. Processing of thermally exciting the oxygen-containing gas and supplying the same to the wafer 200 is also referred to as thermal oxidizing.

In this embodiment also, the tendency that the surface on the upper side of the concave portion is easily etched with respect to the surface on the lower side of the concave portion can be cancelled, and the effect similar to that in the embodiments described above can be obtained.

For example, step C may be performed by introducing the atmosphere into the processing chamber after the etching processing. For example, after the etching processing is performed, after purge, atmospheric pressure restoration, and boat unload are performed, and the wafer 200 after the etching processing is exposed to the atmosphere, whereby step C may be performed. In these cases, O₂, H₂O and the like contained in the atmosphere is used as the oxidizing agent to oxidize the surface of the concave portion after at least a part of the concave portion is etched. Even in these cases, effects similar to those in the embodiments described above can be obtained.

For example, the surface of the concave portion included in the wafer 200 may include a substance containing a metal element such as tungsten (W), molybdenum (Mo), ruthenium (Ru), titanium (Ti), zirconium (Zr), hafnium (Hf), and aluminum (Al), and oxygen, that is, a metal oxide. The surface of the concave portion can include a W film, an Mo film, an Ru film, a TiN film, a ZrN film, an HN film, or an AlN film on a surface of which a natural oxide film is formed, that is, a conductive or non-conductive metal-containing film on a surface of which a natural oxide film is formed. In the present embodiment also, effects similar to those in the embodiments described above can be obtained.

Preferably, the recipe used in each processing is individually prepared according to processing contents and is recorded and stored in the memory 121c via an electric communication line or the external memory 123. When each processing is started, the CPU 121a preferably appropriately selects an appropriate recipe from among a plurality of recipes recorded and stored in the memory 121c according to the processing contents. Therefore, it is possible to perform the etching processing on films with various film types, composition ratios, film qualities, and thicknesses of film with excellent reproducibility by using the processing apparatus. It is possible to reduce a burden on an operator, and it is possible to quickly start each processing while avoiding an operation error.

The recipe described above is not limited to a newly created recipe, but may be prepared by, for example, changing the existing recipe already installed in the processing apparatus. In a case of changing the recipe, the changed recipe may be installed in the processing apparatus via an electric communication line or a recording medium in which the recipe is recorded. The existing recipe already installed in the processing apparatus may be directly changed by operating the input/output device 122 included in the existing processing apparatus.

In the embodiments described above, an example has been described in which the etching processing is performed by using a batch-type processing apparatus that processes a plurality of substrates at a time. The present disclosure is not limited to the embodiments described above, and can be suitably applied to a case of performing the etching processing by using a single wafer type processing apparatus that processes one or more substrates at a time, for example. In the embodiments described above, an example of performing the etching processing using the processing apparatus including a hot wall type of processing furnace has been described. The present disclosure is not limited to the embodiments described above, and can be suitably applied to a case of performing the etching processing by using a processing apparatus including a cold wall type processing furnace.

In the embodiments described above, an example has been described in which the above-described processing sequence is performed in the same processing chamber of the same processing apparatus (in-situ). The present disclosure is not limited to the embodiments described above, and for example, any step and any other step of the above-described processing sequence may be performed in different processing chambers of different processing apparatuses (ex-situ), or may be performed in different processing chambers of the same processing apparatus.

Even in a case where such processing apparatuses are used, each processing can be performed in accordance with processing procedures and processing conditions similar to those in the embodiments described above and variations, so that effects similar to those in the embodiments described above and variations can be obtained.

The embodiments described above and variations can be used in combination as appropriate. The processing procedures and processing conditions at that time can be similar to the processing procedures and processing conditions in the embodiments described above and variations, for example.

According to the present disclosure, it becomes possible to conformally etch a surface of a concave portion included in a substrate.

What is claimed is:

1. A processing method comprising:
etching at least a part of a surface of a concave portion by performing a cycle a predetermined number of times, the cycle including:
(a) exciting and supplying a modifying agent to a substrate including the concave portion, the surface of which includes a substance containing oxygen, to change an oxygen concentration on a surface of an upper portion of the concave portion; and
(b) supplying an etching agent to the substrate in which the oxygen concentration on the surface of the upper portion of the concave portion is changed.

2. The processing method according to claim 1, wherein in (a), an excited species generated by exciting the modifying agent is supplied to the substrate.

3. The processing method according to claim 1, wherein in (a), the modifying agent is excited into a plasma state and is supplied to the substrate.

4. The processing method according to claim 1, wherein in (a), an excited species generated by exciting the modifying agent into a plasma state is supplied to the substrate.

5. The processing method according to claim 1, wherein the modifying agent includes at least one selected from the group of a reducing agent or an oxidizing agent.

6. The processing method according to claim 1, wherein the modifying agent includes at least one selected from the group of a hydrogen-containing gas, a deuterium-containing gas, or an oxygen-containing gas.

7. The processing method according to claim 1, wherein in (a), the substrate is subjected to at least one selected from the group of hydrogen-containing plasma processing, deuterium-containing plasma processing, inert gas plasma processing, oxygen-containing plasma processing, or thermal oxidizing.

8. The processing method according to claim 1, wherein in (a), the oxygen concentration on the surface of the upper portion of the concave portion is made different from an oxygen concentration on a surface of a portion other than the upper portion of the concave portion.

9. The processing method according to claim 1, wherein the surface of the concave portion includes an oxide.

10. The processing method according to claim 1, wherein the surface of the concave portion includes a substance containing silicon and oxygen.

11. The processing method according to claim 1, wherein the surface of the concave portion includes a silicon oxide.

12. The processing method according to claim 1, wherein the etching agent contains fluorine.

13. The processing method according to claim 1, wherein the etching agent contains fluorine and hydrogen.

14. The processing method according to claim 1, wherein the etching agent includes a first substance and a second substance, and at least one selected from the group of the first substance or the second substance contains fluorine.

15. The processing method according to claim 14, wherein in (b), the first substance and the second substance are alternately supplied.

16. The processing method according to claim 1, wherein
in a case where a ratio of an etching rate on the surface of the upper portion of the concave portion to an etching rate on a surface of a lower portion of the concave portion by the etching agent in a case where (a) is not performed is set to ERRA, and
a ratio of an etching rate on the surface of the upper portion of the concave portion to an etching rate on the surface of the lower portion of the concave portion by the etching agent in a case of performing (a) is set to ERRB, a ratio of ERRB to ERRA (ERRB/ERRA) is set to 0.01 or larger and smaller than 1.

17. The processing method according to claim 1, further comprising (c) oxidizing the surface of the concave portion after etching at least a part of the concave portion.

18. The processing method according to claim 1, further comprising (c) uniformizing the oxygen concentration of the surface of the concave portion after etching at least a part of the concave portion.

19. A method of manufacturing a semiconductor device, the method comprising the method according to claim 1.

20. A processing apparatus comprising:
a modifying agent supply system that supplies a modifying agent to a substrate;
an etching agent supply system that supplies an etching agent to the substrate;
an exciter that excites the modifying agent; and
a controller configured to be capable of controlling the modifying agent supply system, the etching agent supply system, and the exciter so as to perform processing of etching at least a part of a surface of a concave portion by performing a cycle a predetermined number of times, the cycle including:
(a) exciting and supplying the modifying agent to a substrate including the concave portion, the surface of which includes a substance containing oxygen, to change an oxygen concentration on a surface of an upper portion of the concave portion, and (b) supplying the etching agent to the substrate in which the oxygen concentration on the surface of the upper portion of the concave portion is changed.

21. A non-transitory computer-readable recording medium storing a program that causes, by a computer, a processing apparatus to perform:
etching at least a part of a surface of a concave portion by performing a cycle a predetermined number of times, the cycle including:
(a) exciting and supplying a modifying agent to a substrate including the concave portion, the surface of which includes a substance containing oxygen, to change an oxygen concentration on a surface of an upper portion of the concave portion, and
(b) supplying an etching agent to the substrate in which the oxygen concentration on the surface of the upper portion of the concave portion is changed.
